(19) United States
(12) Patent Application Publication
(10) Pub. No.: US 2007/0207570 A1
(43) Pub. Date: Sep. 6, 2007

(54) Apparatuses and methods for forming identifying characters on semiconductor device and wafers

(75) Inventors: Jin-phil Choi, Hwaseong-si (KR); Byong-cheol Park, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/703,127

(22) Filed: Feb. 7, 2007

(30) Foreign Application Priority Data
Feb. 7, 2006 (KR) 20-2006-0011570

(51) Int. Cl. H01L 21/00

(52) U.S. Cl. 438/106

(57) ABSTRACT

An apparatus for forming identifying characters on semiconductor devices includes a laser generation unit, a laser transmission unit, a stage and a control unit. The laser generation unit may generate a laser beam having a pulse duration shorter than a heat diffusion time of a wafer. The laser transmission unit may transmit the laser beam to vary a path of the laser beam. The wafer may be mounted on the stage and, and the control unit may control the laser generation unit, the laser transmission unit and the stage.

### PRIORITY STATEMENT

This non-provisional U.S. patent application claims priority under 35 U.S.C. § 119 to Korean Patent Application No. 10-2006-0011570 filed on Feb. 7, 2006 in the (Korean Intellectual Property Office (KIPO), the entire contents of which are incorporated herein by reference.

### BACKGROUND

### Description of the Related Art

Related art wafers used to manufacture semiconductor devices may have intrinsic identifying (or identification) characters. An identifying character may include a combination of characters, numbers, etc. and may be used to identify the wafer. For example, the identifying character of the wafer may be used to identify wafers on which different elements are formed. In another example, the identifying character of a wafer may be used to check the order of processes that have already been performed or are to be performed.

Related art apparatuses for labeling wafers with identifying characters use laser beams. In one example related art apparatus, a laser beam having higher or relatively high energy is radiated on an area of the wafer to etch a particular area (hereinafter, referred to as “spot”), thereby recording an intrinsic mark including a combination of characters, numbers, etc. However, if a laser beam (e.g., a nanosecond laser beam) having a pulse duration longer than a heat diffusion time of the wafer is used, a portion of the heat energy of the laser beam may be transferred into the wafer to melt environs or surroundings of the identifying character. Accordingly, bumps and/or debris may be formed in the vicinity of, or area surrounding, the spot. The bumps and/or the debris may pollute the wafer during subsequent processes resulting in defective semiconductor products.

In another example related art apparatus, a laser beam having lower or relatively low energy is radiated on an area of the wafer to etch a spot. A laser beam having a relatively long pulse duration has a relatively low peak pulse power (e.g., energy per area), which may form a spot having a relatively low aspect ratio. In this example, if films are continuously layered on the spot having a low aspect ratio during subsequent processes, reading the identifying character may be more difficult due to reduced legibility.

### SUMMARY

Example embodiments provide apparatuses and methods for forming identifying characters on semiconductor wafers, which may suppress and/or prevent generation of byproducts and/or form identifying characters using spots with higher aspect ratios.

Example embodiments provide wafers that include an identifying character obtained by forming a spot having higher aspect ratio without generating byproducts.

According to at least one example embodiment, an apparatus for forming identifying characters on a semiconductor device may include a laser generation unit, a laser transmission unit, a stage and/or a control unit. The laser generation unit may generate a laser beam having a pulse duration shorter than a heat diffusion time of a wafer. The laser transmission unit may transmit the laser beam to vary a path of the laser beam. The wafer may be arranged on a stage, and the control unit may control the stage, the laser generation unit and/or the laser transmission unit.

At least one other example embodiment provides a method of forming identifying characters on a semiconductor device. According to at least this example embodiment, a wafer may be arranged on a wafer stage, and a laser beam having a pulse duration shorter than a heat diffusion time of the wafer may be generated. The laser beam may be transmitted along a path using a plurality of mirrors of a laser path transmission unit, and the laser beam may be focused using a focusing lens unit. The wafer may be labeled using the laser beam to form an identifying character on the wafer.

According to at least one other example embodiment, a wafer may include an identifying character formed by arraying a plurality of spots having an aspect ratio of greater than or equal to about 0.14, or by lines having an aspect ratio of greater than or equal to about 0.14.

According to at least some example embodiments, an aspect ratio of a spot formed on the wafer using the laser beam is greater than or equal to about 0.14. A unit of the pulse duration may be a femtosecond, and the pulse duration may be, for example, less than or equal to about 120 fs. A wavelength of the laser beam may be about 800 nm. The laser beam has a peak pulse power greater than or equal to about 1 tera watt. The laser generation unit may include a titanium sapphire laser source. The laser transmission unit may include a laser path transmission unit having a plurality of mirrors for varying the path of the laser beam. For example, the plurality of mirrors may include mirrors having a reflectance sufficient to totally reflect the laser beam. The laser transmission unit may further include a transmissive focusing lens unit configured to focus the laser beam. The stage moves in at least three axises direction to label the wafer.

According to at least some example embodiments, an apparatus may further include a shutter arranged between the laser generation unit and the laser transmission unit and an expander arranged between the shutter and the laser transmission unit. The shutter may be configured to open and close in accordance with operation of the laser generation unit. The expander may be configured to amplify the laser beam passing through the shutter.

According to at least some example embodiments, the wafer may be labeled by forming a spot on the wafer using the focused laser beam, and shifting the stage in at least three axises direction to a next spot formation location after formation of the spot is completed. The laser beam may be continuously moved along a path of the spot to form the identifying character. Spots may be formed to have a diameter of about 70 μm and a depth of about 10 μm.

### BRIEF DESCRIPTION OF THE DRAWINGS

The present invention will become more apparent by describing in detail example embodiments thereof with reference to the attached drawings, in which:

FIG. 1 is a view illustrating an apparatus for forming identifying characters, according to an example embodiment;

FIG. 2 is a flowchart illustrating a method of forming identifying characters, according to an example embodiment;

FIG. 3 is a view illustrating a wafer according to an example embodiment;

FIGS. 4A and 4B are view illustrating the dot array type and line scanning type of identifying characters ‘7’ according to FIG. 3;

FIGS. 5A and 5B illustrate examples of identifying characters formed using a nanosecond laser and a femtosecond laser; and

FIGS. 6A and 6B are sectional views illustrating aspect ratios according to FIG. 5.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

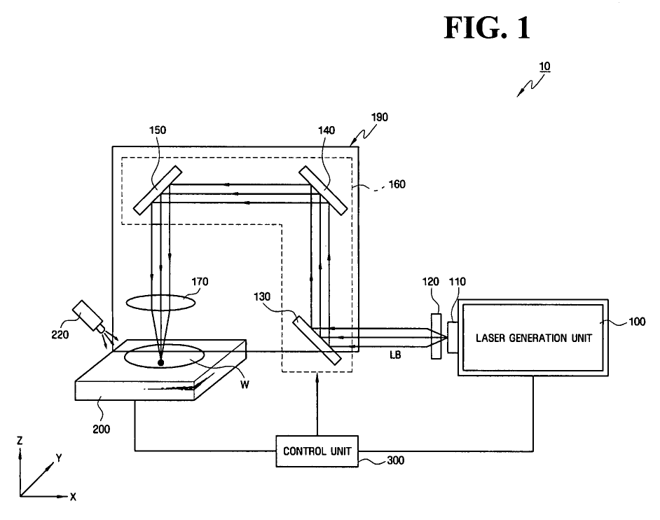

FIG. 1 is a view illustrating an apparatus for forming identifying characters according to an example embodiment.

Referring to FIG. 1, an apparatus 10 for forming identifying characters may include a laser generation unit 100, a laser transmission unit 190, a wafer stage 200 and/or a control unit 300.

The laser generation unit 100 may generate a laser beam LB having a pulse duration shorter than a heat diffusion time of a wafer. The heat diffusion time of the wafer is a time required to transfer heat through the wafer. The heat may be partially converted from energy applied to the wafer, for example, via the laser beam LB. The heat diffusion time of the wafer may be on a picosecond level.

As is the case with related art apparatuses for forming identifying characters on semiconductor devices, if the pulse duration of the pulse type laser beam is longer than the heat diffusion time of the wafer, the environs of a spot may be melted while forming the spot. Accordingly, bumps and/or debris may be formed and protrude from the wafer in the vicinity of the spot. The protruding bumps in the vicinity of the spot may be polished during a subsequent chemical mechanical polishing (CMP) process, which may result in wafer pollution. Further, if environs of the spot melt, a crystalline structure in the vicinity of the spot may be different from an initial or original crystalline structure of the wafer (e.g., recast layer). During subsequent heat treatment processes (e.g., an annealing process), the wafer may be deformed (e.g., locally) and/or cracks may occur on the wafer due to different crystalline structures. This may result in a relatively large heat affected zone (HAZ) that is sensitive to heat.

The unit of the pulse duration of the laser beam LB generated by the laser generation unit 100, according to an example embodiment, may be a femtosecond (fs). For example, the pulse duration of the laser beam LB may be about 120 fs or less, and a wavelength of the laser beam may be about 800 nm. Accordingly, because the radiation pulse duration is shorter than the heat diffusion time of the laser beam LB, energy of the laser beam LB may be present only in a spot region and melting of environs may be suppressed while the spot is formed on wafer W. As a result, a state of only the substance present in the region may be changed. Hence, the size of a heat affected zone (HAZ) created during a labeling process may be reduced and/or the labeling process may be performed without creating a HAZ. In addition, formation of bumps, debris and/or deformation of the crystalline structure due to heat diffusion may be suppressed and/or prevented.

Furthermore, peak pulse power of the laser beam LB may be, for example, about 1 tera watt or more. This higher or relatively high peak pulse power may be used to form a spot having a higher or relatively high aspect ratio. For example, the spot may be formed to have a diameter of about 70 μm and a depth of about 10 μm. As a result, the aspect ratio may be improved by about four times or more in comparison to an aspect ratio of a spot in the related art, such that the aspect ratio may be about 0.14. An increase in aspect ratio, may suppress and/or prevent clogging of openings of the spot when films are layered (e.g., continuously) through processes, such as chemical vapor deposition (CVD). Accordingly, the identifying character having increased identifying ability and/or improved legibility may be formed.

A laser source of the femtosecond laser beam LB may be, for example, a titanium sapphire laser or other similar laser.

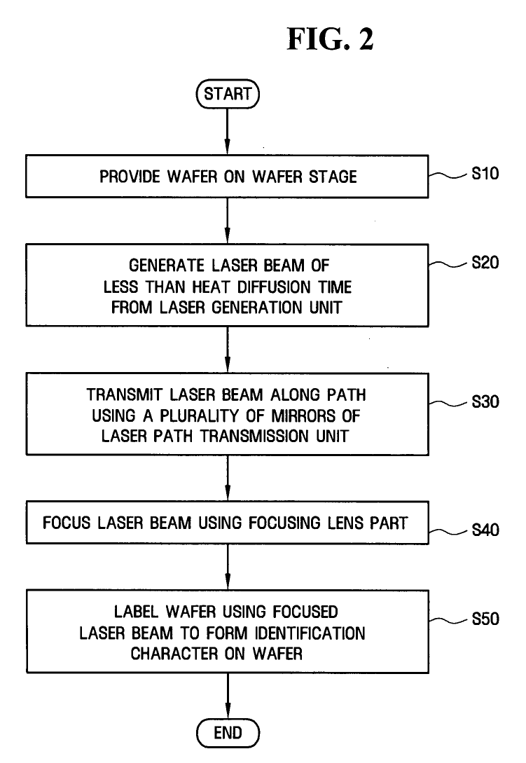

Referring still to FIGS. 1 and 2, the laser beam LB generated by the laser generation unit 100 may be transmitted through a shutter 110 and an expander 120 to the laser transmission unit 190. The shutter 110 may be provided at the front of the laser generation unit 100, and may transmit the laser beam LB there through. For example, when the laser beam LB is radiated, the shutter 110 may be open, but when the laser beam LB is not radiated, the shutter 110 may be closed. FIG. 1 shows the shutter 110 arranged at the front of the laser generation unit 100, however, the position of the shutter 110 is not limited to the front of the laser generation unit. For example, alternatively, the shutter 110 may be provided at the front of a focusing lens unit 170. In at least some example embodiments, the shutter 110 may selectively inhibit the path of the laser beam LB.

Expander 120 may amplify the laser beam LB passing through the shutter 110. For example, the expander 120 may increase an outer diameter of the laser beam LB to suppress and/or prevent damage to the laser transmission unit 190 through which the laser beam LB is transmitted. The expander 120 may also increase the life span of the laser transmission unit 190. A magnification of the outer diameter using the expander 120 may be controlled by the control unit 300.

The laser transmission unit 190 may include a laser path transmission unit 160 and/or a focusing lens unit 170. The laser transmission unit 190 may change a path of the laser beam LB to direct the laser beam toward the wafer stage 200. The laser path transmission unit 160 may include a plurality of reflective surfaces such as mirrors 130, 140 and/or 150 for changing the path of the laser beam LB. According to example embodiments, however, the reflective surfaces are not limited to mirrors, but may be any suitable partially or completely reflective surface.

A first mirror 130 arranged at a position of the laser path transmission unit 160 may reflect (e.g., totally or completely reflect) the laser beam LB amplified by the expander 120 to change a direction of the laser beam LB. As shown in FIG. 1, the mirror 130 may direct the laser beam LB toward the second mirror 140.

The second mirror 140 may face a reflective surface of the first mirror 130 to reflect (e.g., totally or completely) reflect the laser beam LB transmitted from the first mirror 130 toward the third mirror 150.

The third mirror 150 may face a reflective surface of the second mirror 140 to reflect (e.g., totally or completely) the laser beam LB transmitted from the second mirror 140 toward the wafer stage 200. As described above, the laser beam LB may be transmitted while the direction of the laser beam LB is changed by using a plurality of reflective surfaces such as mirrors 130, 140 and/or 150. However, the plurality of reflective surfaces may be optical elements capable of reflecting a laser having a wavelength of about 800 nm. For example, one or more of mirrors 130, 140 and/or 150 may be a Galvanometer mirror. For the convenience of description, in example embodiments, only three mirrors 130, 140 and 150 are described. However, the number of mirrors may be increased or decreased depending on the configuration of the apparatus. In one alternative example, a splitter and a dichroic mirror may be provided to divide the laser beam in a multi-beam system.

The focusing lens unit 170 may focus the laser beam LB reflected by the third mirror 150 on an area of the wafer W. The focusing lens unit 170 may include a focusing lens capable of focusing a laser beam LB having a wavelength of about 800 nm and having higher or relatively high transmissivity.

The wafer stage 200, on which wafer W may be mounted, may be arranged under the focusing lens unit 170, and the wafer W may be labeled (e.g., identifying characters may be formed) using the laser beam LB focused by the focusing lens unit 170. The wafer stage 200 may be moved by a drive unit (not shown). The drive unit may be controlled by the control unit 300 during the labeling process, for example, in X-, Y-, and Z-axis directions.

A gas injection unit 220 may be arranged over the wafer stage 200. The gas injection unit 220 may inject gas (e.g., N₂ or any other suitable gas) to suppress and/or prevent particles generated while forming the spot from being mounted on a surface of the wafer W.

The control unit 300 may control the laser generation unit 100, the laser transmission unit 190, and the wafer stage 200.

Hereinafter, with reference to FIGS. 1 and 2, a detailed description will be given of the operation of an apparatus and method according to an example embodiment.

FIG. 2 is a flowchart illustrating a method of forming identifying characters, according to an example embodiment.

Referring to FIG. 2, at S10, a wafer W may be provided or arranged on a wafer stage 200. At S20, a laser beam LB may be generated by a laser generation unit 100. The laser beam LB may have a pulse duration shorter than a heat diffusion time of the wafer. According to at least this example embodiment, the laser beam LB generated by the laser generation unit 100 may have a femto-second level of pulse duration, and the generated laser beam LB may pass through shutter 110 and be amplified by expander 120.

The generated laser beam LB may be transmitted along a path set using a plurality of mirrors forming a laser path transmission unit 160 at S30. For example, the generated laser beam LB may be incident on a first mirror 130. The laser beam LB incident on the first mirror 130 may be reflected (e.g., totally reflected) and a first reflected beam 131 may be transmitted to a second mirror 140. The first reflected beam 131 incident on the second mirror 140 may be reflected (e.g., totally reflected) and a second reflected beam 141 may be transmitted to a third mirror 150. The second reflected beam 141 incident on the third mirror 150 may be reflected (e.g., totally reflected) and the resulting laser beam LB may be transmitted to a focusing lens unit 170. Thereby, the laser beam LB may be transmitted while the path of the laser beam is changed using a plurality of mirrors. The transmitted laser beam LB may be focused using the focusing lens unit 170 at S40.

At S50, wafer W may be labeled (e.g., one or more identifying characters may be formed on the wafer W) with the focused laser beam LB. According to at least one example embodiment, when labeling, at least one spot (e.g., a plurality of spots) may be formed on the wafer W using the focused laser beam LB. The at least one spots may be formed with the laser beam LB having the pulse duration of about 120 fs and peak pulse power of about 1 tera watt or more. An aspect ratio of the spot may be about 0.14 or more due to the relatively high peak pulse power. Because the pulse duration is shorter than the heat diffusion time of the wafer W, energy of the laser beam LB may be focused on (e.g., only present in) a spot area of the wafer W. Accordingly, formation of bumps or debris in the vicinity of the spot due to heat diffusion may be suppressed and/or prevented reducing the generation of defects caused by pollutants during subsequent processes. While a spot (e.g., a single spot) is formed, the laser beam LB may be radiated repeatedly in pulse form. Once the spot is created, a gas (e.g., N₂ gas) may be injected from a gas injection unit 220 to remove the debris generated during the formation of the spot. The wafer stage 200 may move along the line of the character set by a control unit 300 in X-, Y-, and Z-axis directions, and then shift to a next spot location. While the wafer stage is shifted to the next spot location, the shutter 110 may be closed to suppress and/or prevent the laser beam LB from being generated. The above-mentioned procedure may be repeated to form a plurality of spots, and a plurality of spots may be arrayed to form a dot array type label, which may form the identifying character. However, examples of identifying character labeling may also include a line scanning type instead of the dot array type.

As described above, the femto-second laser beam LB having a reduced affect from heat may enable more precise methods for forming an identifying character (e.g., a line scanning type of identifying character). The path of the spot set by the control unit 300 may be shifted (e.g., continuously) to perform the line scanning type of identifying character labeling.

In the dot array type of identifying character labeling, after one spot is created, the shutter 110 may be closed and shifted to another spot location, and the shutter 110 may be opened. However, in the line scanning type, the shutter 110 need not be opened and closed while moving (e.g., continuously) along the path, which may improve labeling yield.

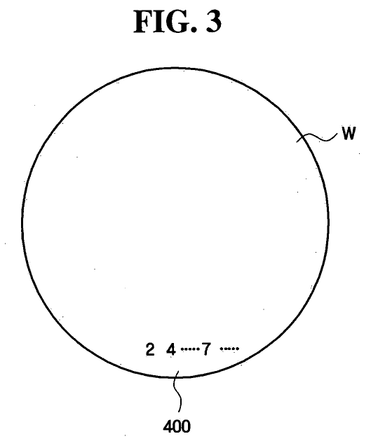

FIG. 3 is a view illustrating a wafer according to an example embodiment. Referring to FIG. 3, the wafer W may include an identifying character 400 formed by the laser beam LB having the pulse duration shorter than the heat diffusion time of the wafer and the identifying character may have an aspect ratio of about 0.14 or more. The identifying character 400 may be formed as a dot array type or a line scanning type.

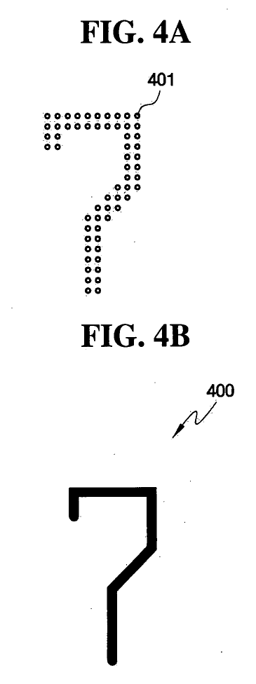

FIGS. 4A and 4B are view illustrating the dot array type and line scanning type of identifying characters, respectively, according to an example embodiment. Referring to FIGS. 4A and 4B, the dot array type of identifying character may be created by the array of spots 401 (FIG. 4A). In the line scanning type (FIG. 4B), the identifying character composed of lines may be formed by moving (e.g., continuously) the laser beam LB along the same or substantially the same path as when forming the dot array type.

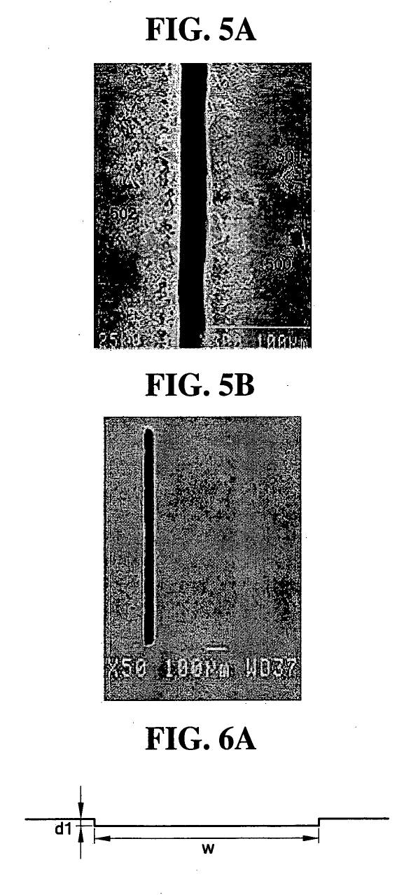

FIGS. 5A and 5B illustrate examples of identifying characters formed using a related apparatus and an apparatus according to an example embodiment, respectively. FIG. 5A shows a line type identifying character formed using a related art nanosecond laser, and FIG. 5B shows the line type of identifying character formed using a femtosecond laser according to an example embodiment.

As shown in FIG. 5A, debris 500, 501, and 502 are formed in the vicinity of the line type of identifying character formed using the related art nanosecond laser. However, in FIG. 5B, there is little or no debris in the vicinity of the line type of identifying character formed using the femtosecond laser thereby providing more precise processing.

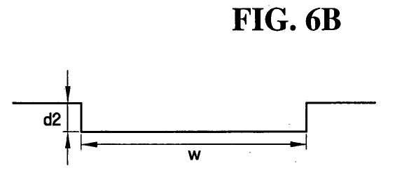

FIGS. 6A and 6B show sectional views illustrating aspect ratios associated with the identifying characters shown in FIGS. 5A and 5B.

With reference to FIGS. 6A and 6B, reference characters w, d1, and d2 denote a diameter of a trench of the spot or the line, a depth of the line type of identifying character that is formed using the related art nanosecond laser (FIG. 6A), and a depth of the line type of identifying character that is formed using a femtosecond laser according to an example embodiment (FIG. 6B), respectively.

As shown, the aspect ratio of the identifying character formed by the femtosecond laser (FIG. 6B) may be higher than the aspect ratio of the identifying character that is formed using the related art nanosecond laser (FIG. 6A). According to at least one example embodiment, the aspect ratio of the identifying character formed using the femtosecond laser may be about four times higher than the aspect ratio of the identifying character formed using the related art nanosecond laser.

Therefore, apparatuses for forming identifying characters, according to example embodiments may be used to perform a higher precision labeling process. In at least some example embodiments, labeling may be performed using the femtosecond laser beam LB having the pulse duration shorter than the heat diffusion time of the wafer to form the identifying character so as to manufacture a semiconductor device having a reduced or no heat affected zone (HAZ) and/or higher identifying ability. Example embodiment may reduce side effects caused by heat diffusion of the wafer using a laser beam having a pulse duration shorter than a heat diffusion time of a wafer. Because the side effects caused by the heat diffusion of the wafer are reduced, generation of defects may be reduced during subsequent processes. In addition, a spot having a higher aspect ratio may be formed using a laser beam having a higher energy per area. A higher aspect ratio may provide a more identifiable labeling.

Although the present invention has been described in connection with the example embodiments, it will be apparent to those skilled in the art that various modifications and changes may be made thereto without departing from the scope and spirit of the invention. Therefore, it should be understood that the above embodiments are not limitative, but illustrative in all aspects.

What is claimed is:

1. An apparatus for forming identifying characters on a semiconductor device, the apparatus comprising:
a laser generation unit configured to generate a laser beam having a pulse duration shorter than a heat diffusion time of a wafer;
a laser transmission unit configured to transmit the laser beam to vary the path of the laser beam;
a stage on which to mount the wafer; and
a control unit configured to control the stage, the laser generation unit and the laser transmission unit.

2. The apparatus of claim 1, wherein an aspect ratio of a spot formed on the wafer using the laser beam is greater than or equal to 0.14.

3. The apparatus of claim 1, wherein a unit of the pulse duration is a femtosecond.

4. The apparatus of claim 1, wherein the pulse duration of the laser beam is less than or equal to 120 fs, and a wavelength of the laser beam is 800 nm.

5. The apparatus of claim 1, wherein the laser beam has a peak pulse power greater than or equal to 1 tera watt.

6. The apparatus of claim 1, wherein the laser generation unit includes a titanium sapphire laser source.

7. The apparatus of claim 1, wherein the laser transmission unit includes, a laser path transmission unit having a plurality of reflective surfaces, the plurality of reflective surfaces being arranged such to direct the laser beam toward the wafer stage.

8. The apparatus of claim 7, wherein the plurality of mirrors includes,
mirrors having a reflectance sufficient to totally reflect the laser beam.

9. The apparatus of claim 1, wherein the laser transmission unit includes,
a transmissive focusing lens unit configured to focus the laser beam.

10. The apparatus of claim 1, wherein the stage moves in at least three axises direction to label the wafer.

11. The apparatus of claim 1, further including,
a shutter arranged between the laser generation unit and the laser transmission unit, the shutter being configured to open and close in accordance with operation of the laser generation unit, and
an expander arranged between the shutter and the laser transmission unit, the expander being configured to amplify the laser beam passing through the shutter.

12. A method of forming identifying characters on a semiconductor device, the method comprising:
generating a laser beam having a pulse duration shorter than a heat diffusion time of a wafer arranged on a wafer stage;
transmitting the laser beam along a path using a plurality of mirrors;
focusing the laser beam; and
labeling the wafer using the laser beam to form an identifying character on the wafer.

13. The method of claim 12, wherein the labeling the wafer further includes,
forming a spot having an aspect ratio of greater than or equal to 0.14 using the laser beam.

14. The method of claim 12, wherein the laser beam has a femtosecond pulse duration.

15. The method of claim 12, wherein the labeling of the wafer includes,
forming a spot on the wafer using the focused laser beam, and
shifting the stage in at least three axises direction to a next spot formation location after formation of the spot is completed.

16. The method of claim 12, wherein the identifying character includes a plurality of arrayed spots.

17. The method of claim 12, wherein the labeling further includes,
continuously moving the laser beam along a path of the spot to form the identifying character.

18. A wafer comprising an identifying character formed using a plurality of arrayed spots having an aspect ratio of greater than or equal to 0.14 or a plurality of lines having an aspect ratio of greater than or equal to 0.14.

19. The wafer of claim 18, wherein the identifying character is formed by a laser beam having a pulse duration that is shorter than a heat diffusion time of the wafer.

20. The wafer of claim 18, wherein the spots are formed to have a diameter of 70 μm and a depth of 10 μm.
